(19) United States
(12) Patent Application Publication
(10) Pub. No.: US 2018/0076256 A1
(43) Pub. Date: Mar. 15, 2018

(54) Array Substrate, Display Panel, and Display Apparatus

(71) Applicant: Beijing Xiaomi Mobile Software Co., Ltd., Beijing (CN)

(72) Inventors: Zhongsheng JIANG, Beijing (CN); Anyu LIU, Beijing (CN)

(73) Assignee: Beijing Xiaomi Mobile Software Co., Ltd., Beijing (CN)

(21) Appl. No.: 15/704,679

(22) Filed: Sep. 14, 2017

(30) Foreign Application Priority Data
Sep. 14, 2016 (CN) 201610827550.X

(51) Int. Cl. H01L 27/146; H01L 27/12; G02F 1/1368; G02F 1/133; G02F 1/1333; G02F 1/1335

(52) U.S. Cl. CPC H01L 27/14678; H01L 27/1255; H01L 27/124; H01L 27/1262; H01L 27/127; H01L 31/102; H01L 27/14685; G02F 1/1368; G02F 1/13318; G02F 1/13338; G02F 1/133512; H01L 27/14692

(57) ABSTRACT

An array substrate, a display panel and a display apparatus are provided. The array substrate includes: a base layer having an upper surface. A thin film transistor is provided in a first region on the upper surface. A photoelectric sensor is provided in a second region on the side of the base layer, which is configured for fingerprint identification. A passivation layer is provided on a side of both the thin film transistor and the photoelectric sensor away from the base layer.

### CROSS-REFERENCE TO RELATED APPLICATION

This application is based on and claims priority of Chinese Patent Application No. 201610827550.X, filed on Sep. 14, 2016, which is incorporated herein by reference in its entirety.

### TECHNICAL FIELD

The present disclosure generally relates to the technical field of displaying, and more particularly to an array substrate, a display panel, and a display apparatus.

### BACKGROUND

With the diversity of encryption/decryption operations of a smart terminal, methods based on fingerprints have drawn more and more attention because fingerprints varies from person to person. Accordingly, fingerprint identification modules become more and more widely integrated in devices such as smart terminals.

Nowadays, a fingerprint identification module is typically provided in a smart terminal (e.g. a handset) in two manners. One of them is to dispose the fingerprint identification module at the back of the smart terminal and the other one is to dispose the module at the front of the smart terminal. The fingerprint identification module disposed at the back is usually located in the upper and middle regions of a casing of the terminal, while the fingerprint identification module disposed at the front is integrated with a HOME key.

However, no matter which of the above manners is adopted, it is necessary to fabricate a separate fingerprint identification module and then dispose the same in a smart terminal, which is a complex manufacturing process.

### SUMMARY

In order to address the deficiency in the related art, the present disclosure provides an array substrate, a display panel and a display apparatus.

According to a first aspect of the present disclosure, an array substrate is provided. The array substrate comprises: a base layer having an upper surface; a thin film transistor in a first region on the upper surface of the base layer; a photoelectric sensor, provided in a second region on the upper surface of the base layer, for fingerprint identification; and a passivation layer provided on a side of both the thin film transistor and the photoelectric sensor away from the base layer.

According to a second aspect of the present invention, a display panel is provided. The display panel comprises an array substrate. The array substrate comprises: a base layer having an upper surface; a thin film transistor in a first region on the upper surface of the base layer; a thin film transistor provided in a first region on the upper surface of the base layer; and a passivation layer provided on a side of both the thin film transistor and the photoelectric sensor away from the base layer.

According to a third aspect of the present disclosure, a display apparatus is provided. The display apparatus comprises a display panel, a backlight module and a touch module. The display panel comprises an array substrate. The backlight module is provided on a side of the array substrate away from a color film substrate of the display panel. The touch module is provided on a side of the color film substrate away from the array substrate, or provided between the array substrate and the color film substrate. The array substrate comprises: a base layer having an upper surface; a thin film transistor provided in a first region on the upper surface of the base layer; a photoelectric sensor, provided in a second region on the upper surface of the base layer, for fingerprint identification; and a passivation layer provided on a side of both the thin film transistor and the photoelectric sensor away from the base layer.

It is to be understood that both the foregoing general description and the following detailed description are exemplary and explanatory only and are not restrictive of the present disclosure.

### BRIEF DESCRIPTION OF THE DRAWINGS

The accompanying drawings, which are incorporated in and constitute a part of this specification, illustrate embodiments consistent with the disclosure and, together with the description, serve to explain the principles of the disclosure.

FIG. 1 is a schematic diagram illustrating a structure of an array substrate according to an aspect of the disclosure.

FIG. 2 is a schematic diagram illustrating a principle of fingerprint identification according to an aspect of the disclosure.

FIG. 3 is a schematic diagram illustrating a structure of another array substrate according to an aspect of the disclosure.

FIG. 4 is a schematic diagram illustrating a structure of a display panel according to an aspect of the disclosure.

FIG. 5 is a schematic diagram illustrating a structure of another display panel according to an aspect of the disclosure.

FIG. 6 is a schematic flowchart illustrating a fabricating method of an array substrate according to an aspect of the disclosure.

FIG. 7 is a schematic flowchart illustrating another fabricating method of an array substrate according to an aspect of the disclosure.

FIG. 8 is a block diagram illustrating a display apparatus according to an aspect of the disclosure.

### DETAILED DESCRIPTION

Reference will now be made in detail to exemplary embodiments, examples of which are illustrated in the accompanying drawings. The following description refers to the accompanying drawings in which the same numbers in different figures represent the same or similar elements unless otherwise indicated. The implementations set forth in the following description of embodiments do not represent all implementations consistent with the disclosure. Instead, they are merely examples of apparatuses and methods consistent with aspects related to the disclosure as recited in the appended claims.

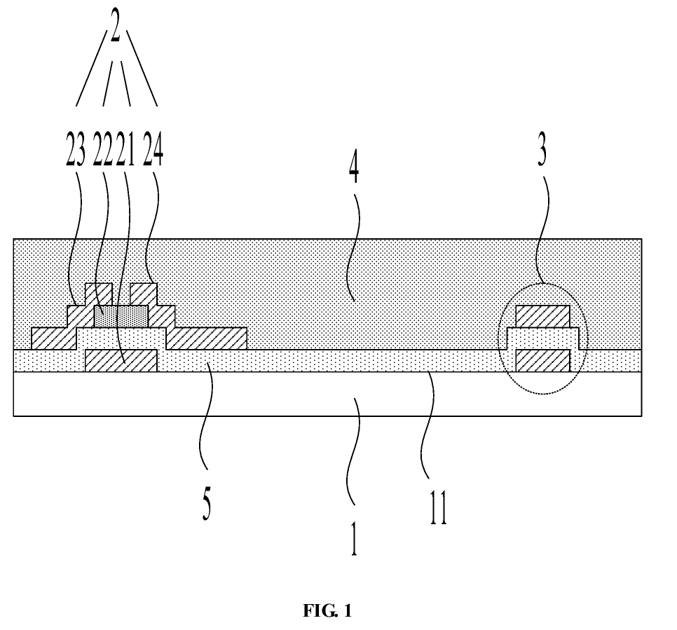

FIG. 1 is a schematic diagram illustrating a structure of an array substrate according to an aspect of the disclosure. As shown in FIG. 1, the array substrate comprises: a base layer 1 having an upper surface 11, a thin film transistor 2 and a photoelectric sensor 3.

In one or more embodiments, the material of the base layer may be glass. However, when the array substrate is suitable for a flexible display apparatus, the material of the base layer may be flexible resin.

The thin film transistor 2 is provided in a first region on the upper surface 11 of the base layer 1. The upper surface 11 may also be referred to as a side of the base layer 1 in the disclosure.

In one or more embodiments, as shown in FIG. 1, the thin film transistor 2 may comprise components, such as a gate 21, an active layer 22, a source 23, a drain 24, etc. A gate insulator layer 5 may be provided between the gate 21 and the active layer 22.

The photoelectric sensor 3 is provided in a second region on the upper surface 11 of the base layer 1, for fingerprint identification.

In one or more embodiments, the photoelectric sensor may be formed on the base layer, through the same process as for the thin film transistor, e.g., through a patterning process.

In one or more embodiments, the structure of the photoelectric sensor is not limited to the structure shown in FIG. 1, and the position of the photoelectric sensor is not limited to the position shown in FIG. 1 and also not limited to being directly formed on a base layer as shown in FIG. 1. For example, the photoelectric sensor may be formed on a thin film transistor. In other words, it may be formed when forming a source and a drain or thereafter. In this case, there may be an overlapping region between the first region and the second region.

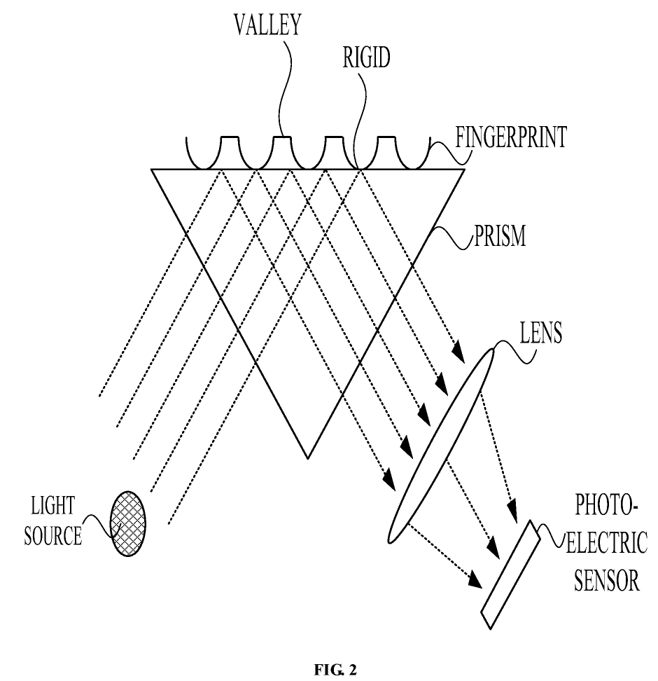

FIG. 2 is a schematic diagram illustrating a principle of fingerprint identification according to an aspect of the disclosure. As shown in FIG. 2, a photoelectric sensor may be a component like a photodiode, a phototriode, a phototransistor, etc. When a user's finger presses on the screen surface, light emitted from a light source may be incident on the fingerprint after passing through prisms and the like. Since heights of valleys and ridges of the fingerprint are different, the ridges closely contact the screen and there are gaps of air between the valleys and the screen. Accordingly, lights reflected at the valleys and ridges after incident thereon are also different. Further, lights incident to the photoelectric sensor after passing through lens are different. The photoelectric sensor may generate a response signal according to the difference between the lights, and determine distribution of valleys and ridges of the fingerprint based on the signal, thereby determining the fingerprint of the user.

The passivation layer 4 is provided on a side of both the thin film transistor 2 and the photoelectric sensor 3 away from the base layer 1.

In one or more embodiments, the passivation layer may be made of an insulating material, which is for example silicon oxide, silicon nitride, etc.

In some embodiments, by disposing a photoelectric sensor on a base layer of an array substrate, the photoelectric sensor can be integrated in the array substrate. In a display apparatus manufactured by using the array substrate, it is possible to place a finger at a position corresponding to a second region of the array substrate for fingerprint identification. Thus, there is no need to set an extra fingerprint identification sensor in the display apparatus, thereby simplifying the manufacturing process and improving the stability and integration of the overall structure.

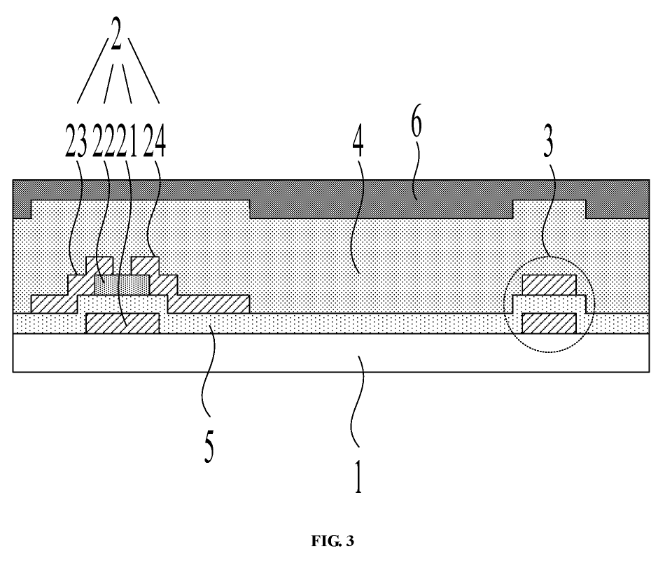

FIG. 3 is a schematic diagram illustrating a structure of another array substrate according to an aspect of the disclosure. As shown in FIG. 3, on the basis of the embodiment illustrated in FIG. 1, the array substrate further comprises a flat layer 6 provided on a side of the passivation layer 4 away from the thin film transistor 2.

The passivation layer 4 illustrated in FIG. 1 is an example, in which the upper surface of the passivation layer 4 is relatively flat. In fact, the thin film transistor and the photoelectric sensor which are below the passivation layer 4 protrude relative to the base layer, so the upper surface of the passivation layer 4 is actually not flat as illustrated in FIG. 3. By further forming a flat layer 6 on the passivation layer 4, the upper surface of the overall structure can be ensured to be relatively flat, thereby facilitating formation of other structures thereon.

Optionally, the photoelectric sensor includes at least one of a photodiode, a phototriode, and a phototransistor.

A user may choose a photodiode and/or a phototriode as a photoelectric sensor for fingerprint sensing according to practical demands.

The present disclosure further provides a display panel comprising the foregoing array substrate.

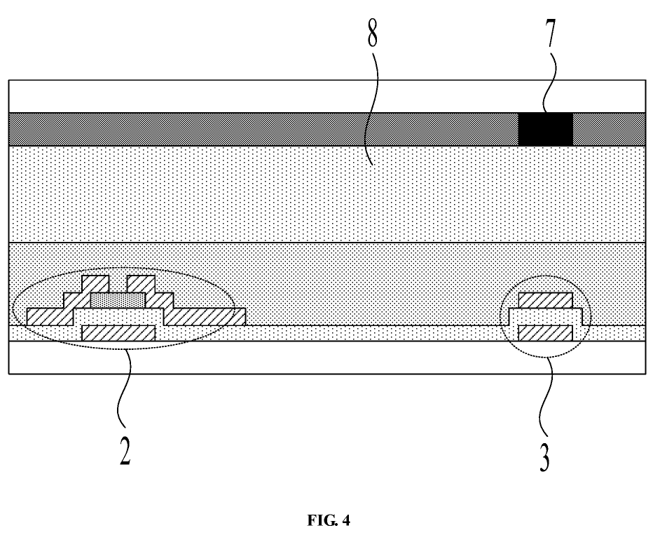

FIG. 4 is a schematic diagram illustrating a structure of a display panel according to an aspect of the disclosure. In FIG. 4, structures of the thin film transistor 2 and the photoelectric sensor 3 are simply illustrated. The display panel comprises the foregoing array substrate, and further comprises a color film substrate and a liquid crystal layer 8.

The color film substrate is disposed opposite to the array substrate. A black matrix 7 is arranged in the color film substrate and disposed opposite to the photoelectric sensor 3.

The liquid crystal layer 8 is provided between the array substrate and the color film substrate.

In one or more embodiments, a color film substrate includes not only a black matrix but also at least one color filtering region provided between elements of the black matrix. Each color filtering region is filled with a color filtering material for the corresponding color. For example, there may be provided a red color filtering region, a green color filtering region, and a blue color filtering region. Furthermore, there may be further provided a white color filtering region.

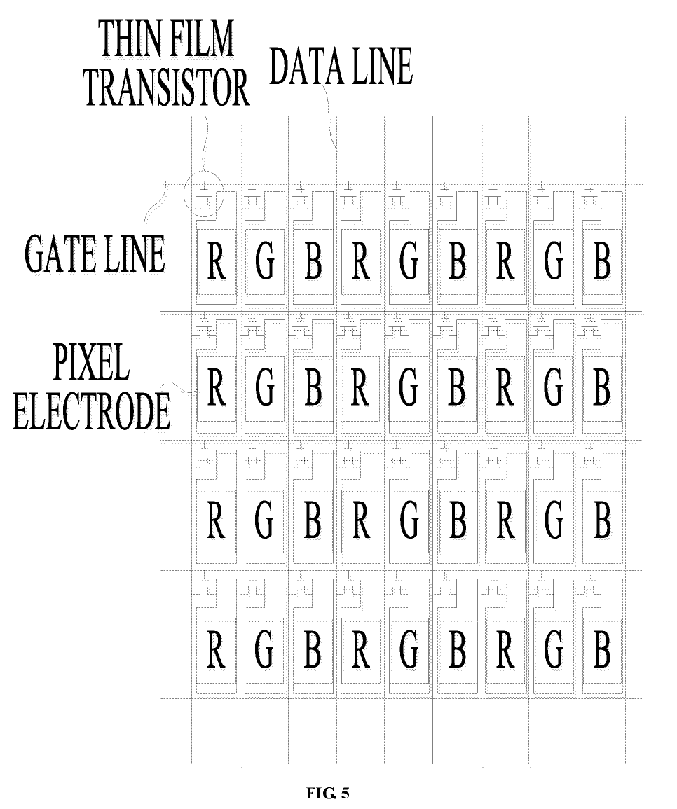

FIG. 5 is a schematic diagram illustrating a structure of another display panel according to an aspect of the disclosure. As shown in FIG. 5, the display panel may include multiple data lines and multiple gate lines. The gate lines and the data lines intersect and define multiple sub pixels. In FIG. 5, characters R, G, B denote red, green, blue sub pixels respectively. In the structure illustrated in FIG. 5, a black matrix (not illustrated in FIG. 5) may be provided at positions where the data lines, the gate lines and/or the thin film transistor are located. Correspondingly, the photoelectric sensor (not illustrated in FIG. 5) may also be provided at these positions so as to be blocked by the black matrix from being seen.

In one or more embodiments, the black matrix may be disposed correspondingly to the thin film transistor, so as to reduce the influence by a scanning signal in a gate of the thin film transistor on the liquid crystal. In this case, the photoelectric sensor may be provided above the thin film transistor, so that positions of the thin film transistor, the photoelectric sensor and the black matrix correspond to each other. In one or more embodiments, although it is possible to fabricate a photoelectric sensor by using transparent material, the photoelectric sensor may decrease light transmittance of its corresponding regions, thereby affecting the aperture opening ratio of the display panel. By correspondingly disposing the photoelectric sensor and the black matrix, regions corresponding to the black matrix become non-transparent due to existence of the black matrix. Thus, even if photoelectric sensors are disposed in these regions, the light transmittance is not decreased. Accordingly, the aperture opening ratio of the display panel can be increased as compared with the case in which photoelectric sensors are disposed at other positions.

The present disclosure further provides a display apparatus, which comprises the foregoing display panel and further comprises a backlight module and a touch module.

The backlight module is provided on a side of the array substrate away from the color film substrate.

In one or more embodiments, the backlight module may comprise a light guide plate and a light bar provided on a side of the light guide plate. Light emitted from the light bar is incident on the light guide plate, turned into light emitted from an area light source through refraction and reflection at the light guide plate and then incident towards a display panel.

The touch module is provided on a side of the color film substrate away from the array substrate, or provided between the array substrate and the color film substrate.

In one or more embodiments, the touch module may be a self-inductance capacitor or a mutual-inductance capacitor. When the touch module is provided on a side of the color film substrate away from the array substrate, its structure may be a One Glass Solution (OGS) structure (e.g., the touch module is provided on protective glass on the outer side of the color film substrate). On the other hand, when the touch module is provided between the array substrate and the color film substrate, its structure may be an On Cell structure (e.g., the touch module is provided between a polarizer on a side of the color film substrate and the base layer) or an In Cell structure (e.g., the touch module is provided on the array substrate). The user may choose a specific structure of the touch module according to practical demands.

Optionally, the foregoing display apparatus further comprises a control chip.

The control chip is electrically connected to the thin film transistor, the photoelectric sensor and the touch module. The touch module transmits a control signal to the control chip when sensing a touch signal at a position corresponding to the photoelectric sensor, so as to control the photoelectric sensor and the thin film transistor corresponding to the photoelectric sensor to start operation.

In one or more embodiments, the control chip may comprise a first integrated circuit, a second integrated circuit, and a signal generator electrically connected to these two integrated circuits, respectively.

The signal generator is electrically connected to the touch module, and generates and sends a starting signal to the first integrated circuit and the second integrated circuit when receiving a control signal from the touch module. The first integrated circuit may be electrically connected to the thin film transistor via a gate line, and transmits a scanning signal to the gate of the thin film transistor when receiving the starting signal, making the thin film transistor start operation. On the other hand, when receiving the starting signal, the second integrated circuit may control the photoelectric sensor to start operation through wires connected with the photoelectric sensor. Thus, when the user touches the position corresponding to the photoelectric sensor, identification of the user's fingerprint is triggered.

In one or more embodiments, the thin film transistor and the photoelectric sensor may be connected with one control chip. This control chip may transmit a scanning signal to the thin film transistor, and determine fingerprint information based on the electrical signal from the photoelectric sensor. Thus, a first wire connected to the thin film transistor and a second wire connected to the photoelectric sensor can be drawn from the single chip. This facilitates parallel arrangement of the first wire and the second wire and eliminates intersection of the first wire and the second wire, thereby decreasing the complexity of wiring.

The control chip may be a Chip On Glass (COG). In other words, the control chip may be directly formed on the base layer of the array substrate, so as to decrease the volume of the display apparatus where the array substrate is located.

Optionally, the display apparatus further comprises a data line and a pixel electrode. The thin film transistor is electrically connected to the data line and the pixel electrode, and the data line transmits a data signal to the pixel electrode via the thin film transistor. The control chip adjusts the data signal transmitted through the data line corresponding to the photoelectric sensor when receiving the control signal, so that light emitted from the backlight module becomes monochromatic light or white light after passing through the display panel.

In one or more embodiments, the data line may be electrically connected to a source of the thin film transistor, while the pixel electrode may be electrically connected to a drain of the thin film transistor through a through hole in the passivation layer. Thus, when the thin film transistor is enabled (namely, turned on), the data signal on the data line may be transmitted to the pixel electrode through a source, an active layer and a drain of the thin film transistor.

In one or more embodiments, light sensed by a photoelectric sensor is incident from a light guide plate towards a display panel, then towards a finger through the display panel, and is next reflected towards the photoelectric sensor by the finger. As currents induced from lights of different colors by the photoelectric sensor are different, when the light from the display panel to the finger is not white light but light of mixed colors, the photoelectric sensor may receive, at different regions thereof, reflected lights of different colors, due to spectroscopic effect exerted on the light of mixed colors by material of the display panel. Accordingly, the photoelectric sensor produces an unstable current, which affects the detection result.

When the light from the display panel to the finger is white light, light finally reaching the photoelectric sensor is still mixed into white light, even after undergoing the spectroscopic effect of the material in the display panel. When the light from the display panel to the finger is monochromatic light, no spectroscopic effect will occur during propagation of the light and the light finally reaching the photoelectric sensor is still monochromatic light.

As such, by adjusting the data signal when receiving the control signal, the control chip may adjust the voltage of the pixel electrode to change the deflection of the liquid crystal at the position of the photoelectric sensor, so that red, green and blue sub pixels at the position are all enabled. Accordingly, all the white light incident from the backlight module to the display panel can be emitted out and remain white light after passing through the display panel. Further, the light reflected by the user's finger and the light incident on the photoelectric sensor are still white light. Alternatively or additionally, it is possible to enable only a single color sub pixel (e.g., enable the red sub pixel), so that the white light can pass through only the area of the red sub pixel and is filtered by red color filtering material to leave only read light to be emitted out. Accordingly, the light emitted from the display panel is monochromatic red light. Further, the light reflected by the user's finger and the light incident on the photoelectric sensor are also red light.

Optionally, the display apparatus further comprises: a status detection circuit configured to detect a working status of the display apparatus and transmit the detected working status to the touch module. The touch module determines whether the display apparatus is in a status of being ready for fingerprint identification when sensing a touch signal at a position corresponding to the photoelectric sensor, and transmits the control signal to the control chip if the display apparatus is in the status of being ready for fingerprint identification.

As the photoelectric sensor is provided in the array substrate (that is, in an effective display region of the display panel), the user may click on an area corresponding to the photoelectric sensor even when performing an operation not requiring fingerprint identification. In this case, waste of power will be incurred if the photoelectric sensor is started.

In one or more embodiments, by further detecting a working status of the display apparatus, it may be determined whether the display apparatus is in a status of being ready for fingerprint identification when a user clicks on a position corresponding to the photoelectric sensor. The status of being ready for fingerprint identification may include a screen locked status, a fingerprint payment verification status, or other status that needs to invoke fingerprint identification for the system or a particular application. When the display apparatus is in such a status, it can be determined that the operation of clicking the position corresponding to the photoelectric sensor by the user requires fingerprint identification and the photoelectric sensor is started to operate then. As such, waste of power and loss caused by frequent switching on and off of the photoelectric sensor can be can effectively avoided.

Optionally, the display apparatus further comprises: a first chip electrically connected to the photoelectric sensor and the touch module; and a second chip electrically connected to the thin film transistor and the touch module. The touch module transmits control signals respectively to the first chip and the second chip when sensing a touch signal at a position corresponding to the photoelectric sensor, so that the first chip controls the photoelectric sensor to start operation and the second chip controls the thin film transistor corresponding to the photoelectric sensor to start operation.

In one or more embodiment, one chip transmits a scanning signal to the thin film transistor and a different chip processes an electrical signal from the photoelectric sensor. Compared with the embodiment in which one control chip not only transmits a scanning signal to the thin film transistor but also processes an electrical signal from the photoelectric sensor, the structure is less complex and easier to be fabricated since the first chip and the second chip implement partial functions respectively.

Depending on process requirements, it is optional whether the thin film transistor and the photoelectric sensor are connected to respective chips or to one common chip.

Correspondingly to embodiments of the foregoing array substrates, the present disclosure further provides embodiments of a fabricating method of an array substrate.

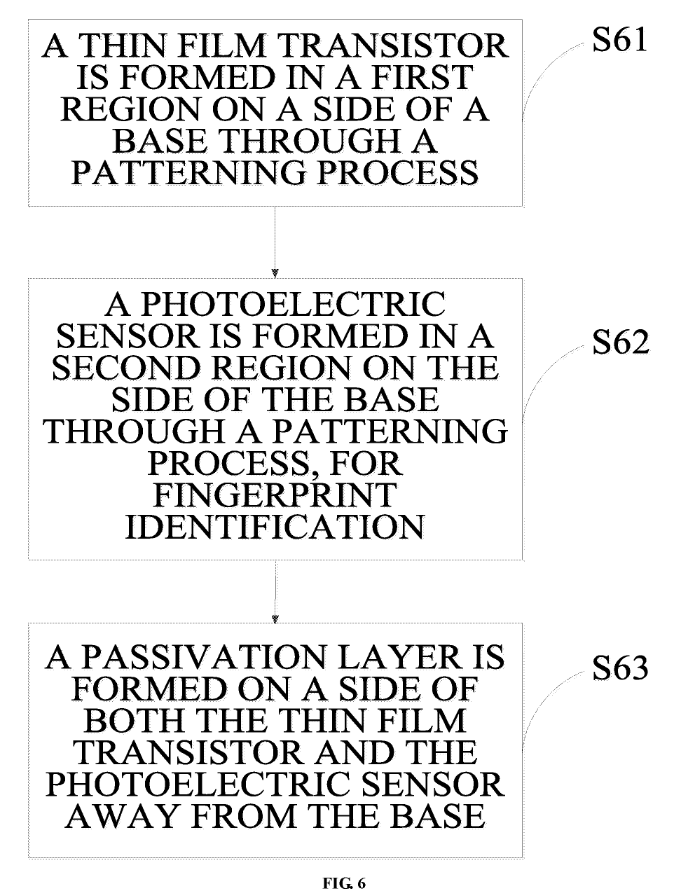

FIG. 6 is a schematic flowchart illustrating a fabricating method of an array substrate according to an aspect of the disclosure. As shown in FIG. 6, the fabricating method comprises the following steps.

At step S61, a thin film transistor is formed in a first region on a side of a base layer through a patterning process.

At step S62, a photoelectric sensor is formed in a second region on the side of the base layer through a patterning process, for fingerprint identification.

At step S63, a passivation layer is formed on a side of both the thin film transistor and the photoelectric sensor away from the base layer.

In one or more embodiments, if the photoelectric sensor is also formed on the base layer, the step S61 and the step S62 may be performed simultaneously. That is, the photoelectric sensor is formed while forming the thin film transistor. If the photoelectric sensor is formed above the thin film transistor, then the step S61 may be performed before the step S62. In addition, an insulation layer may be further disposed above the thin film transistor, to insulate the source and the drain of the thin film transistor from the photoelectric sensor.

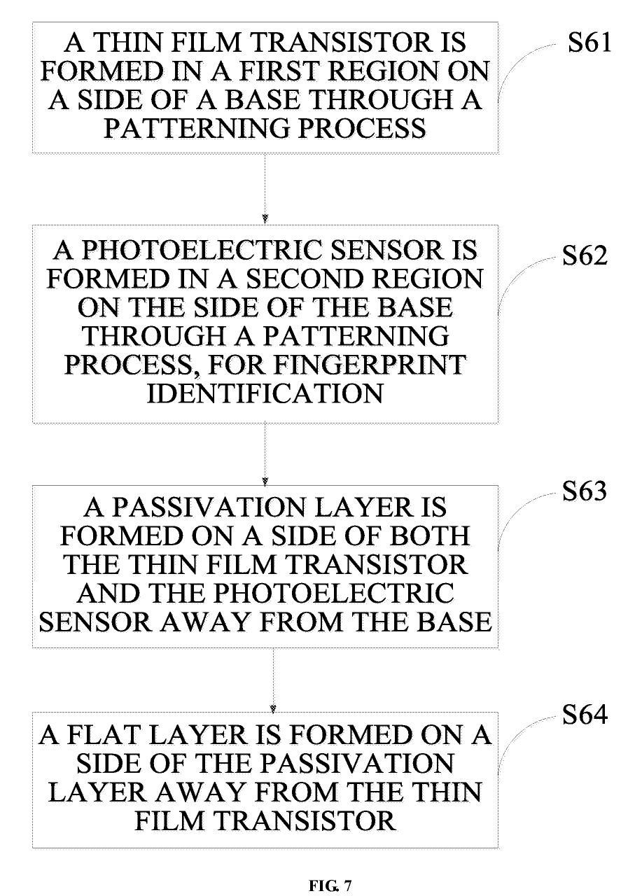

FIG. 7 is a schematic flowchart illustrating another fabricating method of an array substrate according to an aspect of the disclosure. As shown in FIG. 7, on the basis of the embodiment illustrated in FIG. 6, the fabricating method further comprises a step S64.

At step S64, a flat layer is formed on a side of the passivation layer away from the thin film transistor.

Regarding the fabricating method in the above embodiments, the specific manners for implement the individual steps have been described in detail in the embodiments of the related array substrate and will not be elaborated herein.

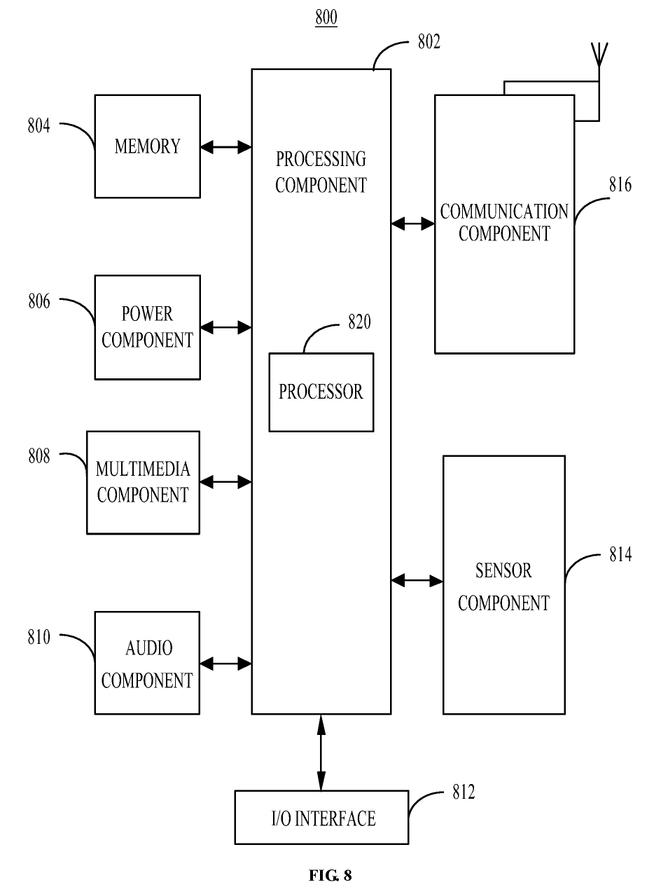

FIG. 8 is a block diagram illustrating a display apparatus 800 according to an aspect of the disclosure. For example, the apparatus 800 may be a mobile phone, a computer, a digital broadcast terminal, a messaging device, a gaming console, a tablet, a medical device, exercise equipment, a personal digital assistant or the like.

Referring to FIG. 8, the apparatus 800 may include one or more of the following components: a processing component 802, a memory 804, a power component 806, a multimedia component 808, an audio component 810, an input/output (I/O) interface 812, a sensor component 814 and a communication component 818. The apparatus 800 may further include an array substrate. The array substrate comprises: a base layer; a thin film transistor provided on one side of the base layer; a photoelectric sensor provided on a side of the thin film transistor away from the base layer and used for fingerprint identification; and a passivation layer provided in a region of the thin film transistor, where the photoelectric sensor is not disposed, and provided on a side of the photoelectric sensor away from the thin film transistor.

The processing component 802 generally controls the overall operations of the apparatus 800, for example, display, phone call, data communication, camera operation and recording operation. The processing component 802 may include one or more processors 820 to execute instructions. In addition, the processing component 802 may include one or more modules to facilitate the interaction between the processing component 802 and other components. For example, the processing component 802 may include a multimedia module to facilitate the interaction between the multimedia component 808 and the processing component 802.

The memory 804 is configured to store various types of data to support the operation performed on the apparatus 800. Examples of such data include any application operated on the apparatus 800, contact data, phonebook data, messages, pictures, video, etc. The memory 804 may be implemented using any type of volatile or non-volatile memory devices, or a combination thereof, such as a static random access memory (SRAM), an electrically erasable programmable read-only memory (EEPROM), an erasable programmable read-only memory (EPROM), a programmable read-only memory (PROM), a read-only memory (ROM), a magnetic memory, a flash memory, a magnetic or optical disk.

The power component 806 provides power to various components of the apparatus 800. The power component 806 may include a power supply management system, one or more power sources, and any other components associated with the generation, management, and distribution of power in the apparatus 800.

The multimedia component 808 includes a screen providing an output interface between the apparatus 800 and the user. In some embodiments, the screen may include a Liquid Crystal Display (LCD) and a Touch Panel (TP). If the screen includes the touch panel, the screen may be implemented as a touch screen to receive input signals from the user. The touch panel includes one or more touch sensors to sense touches, swipes, and gestures on the touch panel. The touch sensors may not only sense a boundary of a touch or swipe action, but also sense a period of time and a pressure associated with the touch or swipe action. In some embodiments, the multimedia component 808 includes a front camera and/or a rear camera. The front camera and the rear camera may receive external multimedia data while the apparatus 800 is in an operation mode, such as a photographing mode or a video mode. Each of the front camera and the rear camera may be a fixed optical lens system or have focus and optical zoom capability.

The audio component 810 is configured to output and/or input audio signals. For example, the audio component 810 includes a microphone (MIC) configured to receive an external audio signal when the apparatus 800 is in an operation mode, such as a call mode, a recording mode, and a voice recognition mode. The received audio signal may be further stored in the memory 804 or transmitted via the communication component 818. In some embodiments, the audio component 810 further includes a speaker to output audio signals.

The I/O interface 812 provides an interface between the processing component 802 and peripheral interface modules, such as a keyboard, a click wheel, buttons, and the like. The buttons may include, but are not limited to, a home button, a volume button, a starting button, and a locking button.

The sensor component 814 includes one or more sensors to provide status assessments of various aspects of the apparatus 800. For instance, the sensor component 814 may detect an open/closed status of the apparatus 800, relative positioning of components, e.g., the display and the keypad, of the apparatus 800, a change in position of the apparatus 800 or a component of the apparatus 800, a presence or absence of user contact with the apparatus 800, an orientation or an acceleration/deceleration of the apparatus 800, and a change in temperature of the apparatus 800. The sensor component 814 may include a proximity sensor configured to detect the presence of nearby objects without any physical contact. The sensor component 814 may also include a light sensor, such as a CMOS or CCD image sensor, for use in imaging applications. In some embodiments, the sensor component 814 may also include an accelerometer sensor, a gyroscope sensor, a magnetic sensor, a pressure sensor or a temperature sensor.

The communication component 818 is configured to facilitate wired or wireless communication between the apparatus 800 and other devices. The apparatus 800 can access a wireless network based on a communication standard, such as WiFi, 2G, or 3G, or a combination thereof. In one exemplary embodiment, the communication component 818 receives a broadcast signal or broadcast related information from an external broadcast management system via a broadcast channel. In one exemplary embodiment, the communication component 818 further includes a near field communication (NFC) module to facilitate short-range communications. For example, the NFC module may be implemented based on a radio frequency identification (RFID) technology, an infrared data association (IrDA) technology, an ultra-wideband (UWB) technology, a Bluetooth (BT) technology, and other technologies.

In exemplary embodiments, the apparatus 800 may be implemented with one or more application specific integrated circuits (ASIC), digital signal processors (DSP), digital signal processing devices (DSPD), programmable logic devices (PLD), field programmable gate arrays (FPGA), controllers, micro-controllers, microprocessors, or other electronic components. The apparatus 800 may use the above circuitries in combination with the other hardware or software components. Each module, sub-module, unit, or sub-unit in the disclosure may be implemented at least partially using the above hardware electronic components.

In exemplary embodiments, there is also provided a non-transitory computer-readable storage medium including instructions, such as included in the memory 804, executable by the processor 820 of the apparatus 800. For example, the non-transitory computer-readable storage medium may be a ROM, a RAM, a CD-ROM, a magnetic tape, a floppy disc, an optical data storage device, and the like.

The terminology used in the present disclosure is for the purpose of describing exemplary embodiments only and is not intended to limit the present disclosure. As used in the present disclosure and the appended claims, the singular forms “a,” “an” and “the” are intended to include the plural forms as well, unless the context clearly indicates otherwise. It shall also be understood that the terms “or” and “and/or” used herein are intended to signify and include any or all possible combinations of one or more of the associated listed items, unless the context clearly indicates otherwise.

It shall be understood that, although the terms “first,” “second,” “third,” etc. may be used herein to describe various information, the information should not be limited by these terms. These terms are only used to distinguish one category of information from another. For example, without departing from the scope of the present disclosure, first information may be termed as second information; and similarly, second information may also be termed as first information. As used herein, the term “if” may be understood to mean “when” or “upon” or “in response to” depending on the context.

Reference throughout this specification to “one embodiment,” “an embodiment,” “exemplary embodiment,” or the like in the singular or plural means that one or more particular features, structures, or characteristics described in connection with an embodiment is included in at least one embodiment of the present disclosure. Thus, the appearances of the phrases “in one embodiment” or “in an embodiment,” “in an exemplary embodiment,” or the like in the singular or plural in various places throughout this specification are not necessarily all referring to the same embodiment. Furthermore, the particular features, structures, or characteristics in one or more embodiments may be combined in any suitable manner.

Other embodiments of the disclosure will be apparent to those skilled in the art from consideration of the specification and practice of the disclosure disclosed here. This application is intended to cover any variations, uses, or adaptations of the disclosure following the general principles thereof and including such departures from the present disclosure as come within known or customary practice in the art. It is intended that the specification and examples be considered as exemplary only, with a true scope and spirit of the disclosure being indicated by the appended claims.

It will be appreciated that the present disclosure is not limited to the exact construction that has been described above and illustrated in the accompanying drawings, and that various modifications and changes can be made without departing from the scope thereof. It is intended that the scope of the disclosure only be limited by the appended claims.

1. An array substrate, comprising:
a base layer having an upper surface;
a thin film transistor in a first region on the upper surface;
a photoelectric sensor in a second region on the upper surface, the photoelectric sensor is configured for fingerprint identification; and
a passivation layer on a upper side of both the thin film transistor and the photoelectric sensor, the upper side being away from the base layer.

2. The array substrate according to claim 1, further comprising:
a flat layer on a side of the passivation layer away from the thin film transistor.

3. The array substrate according to claim 1, wherein the photoelectric sensor comprises at least one of a photodiode, a phototriode, and a phototransistor.

4. A display panel comprising an array substrate, the array substrate comprising:
a base layer having an upper surface;
a thin film transistor in a first region on the upper surface;
a photoelectric sensor, provided in a second region on the upper surface, for fingerprint identification; and
a passivation layer on a side of both the thin film transistor and the photoelectric sensor away from the base layer.

5. The display panel according to claim 4, further comprising:
a color film substrate disposed opposite to the array substrate, wherein at least one black matrix is arranged in the color film substrate and disposed opposite to the photoelectric sensor; and
a liquid crystal layer provided between the array substrate and the color film substrate.

6. The display panel according to claim 5, wherein the array substrate further comprises:
a flat layer provided on a side of the passivation layer away from the thin film transistor.

7. The display panel according to claim 5, wherein the photoelectric sensor comprises at least one of a photodiode, a phototriode, and a phototransistor.

8. A display apparatus, comprising:
a display panel comprising an array substrate;
a backlight module on a side of the array substrate away from a color film substrate of the display panel; and
a touch module on a side of the color film substrate away from the array substrate, or provided between the array substrate and the color film substrate,
wherein the array substrate comprises:
a base layer having an upper surface;
a thin film transistor provided in a first region on the upper surface;
a photoelectric sensor, provided in a second region on the upper surface, for fingerprint identification; and
a passivation layer provided on a side of both the thin film transistor and the photoelectric sensor away from the base layer.

9. The display apparatus according to claim 8, wherein the display panel further comprises:
a color film substrate disposed opposite to the array substrate, wherein at least one black matrix is arranged in the color film substrate and disposed opposite to the photoelectric sensor; and
a liquid crystal layer provided between the array substrate and the color film substrate.

10. The display apparatus according to claim 9, wherein the array substrate further comprises:
a flat layer provided on a side of the passivation layer away from the thin film transistor.

11. The display apparatus according to claim 9, wherein the photoelectric sensor comprises at least one of a photodiode, a phototriode, and a phototransistor.

12. The display apparatus according to claim 8, further comprising:
a control chip electrically connected to the thin film transistor, the photoelectric sensor, and the touch module,
wherein the touch module transmits a control signal to the control chip when sensing a touch signal at a position corresponding to the photoelectric sensor, so as to control the photoelectric sensor and the thin film transistor corresponding to the photoelectric sensor to start operation.

13. The display apparatus according to claim 12, further comprising:
a data line and a pixel electrode, wherein the thin film transistor is electrically connected to the data line and the pixel electrode, and the data line transmits a data signal to the pixel electrode via the thin film transistor,
wherein the control chip adjusts the data signal transmitted through the data line corresponding to the photoelectric sensor when receiving the control signal, so that light emitted from the backlight module becomes monochromatic light or white light after passing through the display panel.

14. The display apparatus according to claim 12, further comprising:
a status detection circuit configured to detect a working status of the display apparatus and transmit the detected working status to the touch module,
wherein the touch module determines whether the display apparatus is in a status of being ready for fingerprint identification when sensing a touch signal at the position corresponding to the photoelectric sensor, and transmits the control signal to the control chip if the display apparatus is in the status of being ready for fingerprint identification.

15. The display apparatus according to claim 8, further comprising:
a first chip electrically connected to the photoelectric sensor and the touch module; and
a second chip electrically connected to the thin film transistor and the touch module,
wherein the touch module transmits control signals respectively to the first chip and the second chip when sensing a touch signal at a position corresponding to the photoelectric sensor, so that the first chip controls the photoelectric sensor to start operation and the second chip controls the thin film transistor corresponding to the photoelectric sensor to start operation.
